(19) United States
(12) Patent Application Publication
(10) Pub. No.: US 2026/0076086 A1
(43) Pub. Date: Mar. 12, 2026

(54) MONOLITHIC META ORGANIC LIGHT-EMITTING DIODE AND METHOD OF MANUFACTURING THE SAME

(71) Applicant: ELECTRONICS AND TELECOMMUNICATIONS RESEARCH INSTITUTE, Daejeon (KR)

(72) Inventors: Yong Hae KIM, Daejeon (KR); Chi-Sun Hwang, Daejeon (KR); Soojung Kim, Daejeon (KR); Jong-Heon Yang, Daejeon (KR); Eui-Sang Yu, Daejeon (KR); Hyunsu Cho, Daejeon (KR); SungHoon Hong, Daejeon (KR)

(21) Appl. No.: 19/306,261

(22) Filed: Aug. 21, 2025

(30) Foreign Application Priority Data
Sep. 11, 2024 (KR) 10-2024-0123924

(51) Int. Cl. H10K 71/00; H10K 59/12; H10K 59/80

(52) U.S. Cl. CPC H10K 71/621; H10K 59/1201; H10K 59/80515

(57) ABSTRACT

A method of manufacturing a monolithic meta organic light-emitting diode (OLED) is provided. The method includes a step of forming a power line on a base substrate, a step of forming a planarization layer covering the power line on the base substrate, a step of forming a bottom electrode electrically connected to the power line on the planarization layer, a step of forming a meta surface layer on the bottom electrode, a step of forming a transparent conductive layer on the meta surface layer, a step of forming an OLED layer on the transparent conductive layer, and a step of forming a top electrode on the OLED layer.

### CROSS-REFERENCE TO RELATED APPLICATION

This application claims the benefit of Korean Patent Application No. 10-2024-0123924 filed on Sep. 11, 2024, which is hereby incorporated by reference as if fully set forth herein.

### BACKGROUND

### Field of the Invention

The present disclosure relates to a monolithic meta organic light-emitting diode (OLED) and a method of manufacturing the same, and more particularly, to a method of manufacturing a monolithic meta-OLED which may include a meta surface so as to provide an ultra-high resolution and high color purity.

### Discussion of the Related Art

Recently, monolithic organic light-emitting diodes (OLEDs) are being used in display devices used in augmented reality (AR) or virtual reality (VR) technology. Monolithic is the term, denoting that elements of an OLED are integrally formed on one substrate, and has advantages where a size and a weight of an OLED are small, and a manufacturing process is simplified.

As the demands for AR and VR having a high sense of reality are increasing, display devices used in AR and VR require a very high resolution also. However, a structure of monolithic OLEDs of the related art has a limitation in implementing an ultra-high resolution (for example, 10,000 ppi) and high color purity.

### SUMMARY

An aspect of the present disclosure is directed to providing a method of manufacturing a monolithic meta organic light-emitting diode (OLED), which may replace a color filter of a conventional monolithic OLED with a meta surface (or a meta surface mirror) and may thus implement an ultra-high resolution and high color purity.

To achieve these and other advantages and in accordance with the purpose of the invention, as embodied and broadly described herein, there is provided a method of manufacturing a monolithic meta organic light-emitting diode (OLED), the method including: a step of forming a power line on a base substrate; a step of forming a planarization layer covering the power line on the base substrate; a step of forming a bottom electrode electrically connected to the power line on the planarization layer; a step of forming a meta surface layer on the bottom electrode; a step of forming a transparent conductive layer on the meta surface layer; a step of forming an OLED layer on the transparent conductive layer; and a step of forming a top electrode on the OLED layer.

In an embodiment, the step of forming the meta surface layer on the bottom electrode may include a step of forming the meta surface layer on the bottom electrode by using a nanoimprint lithography process.

In an embodiment, the step of forming the meta surface layer on the bottom electrode may include: a step of depositing a meta surface material covering the bottom electrode on the planarization layer; a step of coating a resist on the meta surface material; a step of patterning the resist by using a nanoimprint stamp; and a step of etching the meta surface material by using a patterned resist as a mask to form the meta surface layer.

In an embodiment, the meta surface material may be a dielectric or metal.

In an embodiment, when seen from above, the meta surface layer may include a plurality of cylinders arranged in a matrix form.

In an embodiment, the method may further include: between the step of forming the transparent conductive layer on the meta surface layer and the step of forming the OLED layer on the transparent conductive layer, a step of patterning the transparent conductive layer; and a step of forming a pixel define layer representing a boundary of a pixel area on the meta surface layer upward exposed in a process of patterning the transparent conductive layer.

In another aspect of the present invention, there is provided a method of manufacturing a monolithic meta organic light-emitting diode (OLED), the method including: a step of sequentially forming a buffer oxide layer, a metal layer for pixel pad, and a meta surface material on a base substrate; a step of patterning the meta surface material to form a meta surface layer; a step of forming a transparent conductive layer covering the meta surface layer on the metal layer for pixel pad; a step of simultaneously or sequentially patterning the metal layer for pixel pad, the meta surface layer, and the transparent conductive layer by using a pixel mask pattern; a step of removing the pixel mask pattern, and then, forming a pixel define layer filling a space formed in a process of patterning the metal layer for pixel pad, the meta surface layer, and the transparent conductive layer; a step of forming an OLED layer on a patterned transparent conductive layer upward exposed; and a step of forming a top electrode on the OLED layer.

In an embodiment, the step of patterning the meta surface material to form the meta surface layer may include a step of patterning the meta surface material by using a nanoimprint lithography process to form the meta surface layer.

In an embodiment, the step of patterning the meta surface material to form the meta surface layer may include: a step of coating a resist on the meta surface material; a step of patterning the resist by using a nanoimprint stamp; and a step of patterning the meta surface material by using a patterned resist as a mask.

In an embodiment, the meta surface material may be a dielectric or metal.

In an embodiment, the step of patterning the meta surface material to form the meta surface layer may include a step of forming the meta surface layer including a plurality of cylinders arranged in a matrix form by using a nanoimprint lithography process.

In another aspect of the present invention, there is provided a monolithic meta organic light-emitting diode (OLED) including: a circuit substrate; a bottom electrode disposed on the circuit substrate; a meta surface layer having a meta surface structure including a plurality of cylinders disposed on the bottom electrode; a transparent conductive layer disposed between an upper portion of the meta surface layer and the plurality of cylinders; an OLED layer disposed on the transparent conductive layer; and a top electrode disposed on the OLED layer.

In an embodiment, the meta surface layer may include a dielectric or metal.

In an embodiment, the transparent conductive layer may be an indium tin oxide (ITO) layer or a conductive polymer layer.

According to embodiments of the present disclosure, a color filter of a conventional monolithic OLED may be replaced with a meta surface, and thus, an ultra-high resolution and high color purity may be implemented.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

FIG. 1A is a schematic layout illustrating a subpixel of a monolithic meta organic light-emitting diode (OLED) according to an embodiment of the present disclosure, and FIG. 1B is a schematic cross-sectional view illustrating a subpixel of the monolithic meta-OLED illustrated in FIG. 1A.

FIGS. 2A to 2C are cross-sectional views illustrating various structures of a meta surface layer according to an embodiment of the present disclosure.

FIGS. 3A to 3H are cross-sectional views for describing a manufacturing process of a monolithic meta-OLED according to an embodiment of the present disclosure.

FIGS. 4A to 4F are cross-sectional views for describing a manufacturing process of a monolithic meta-OLED according to another embodiment of the present disclosure.

### DETAILED DESCRIPTION OF THE INVENTION

Reference will now be made in detail to the exemplary embodiments of the present disclosure, examples of which are illustrated in the accompanying drawings. Wherever possible, the same reference numbers will be used throughout the drawings to refer to the same or like parts.

In the following description, the technical terms are used only for explaining an exemplary embodiment while not limiting the present invention. The terms of a singular form may include plural forms unless referred to the contrary. The meaning of ‘comprise’, ‘include’, or ‘have’ specifies a property, a region, a fixed number, a step, a process, an element and/or a component but does not exclude other properties, regions, fixed numbers, steps, processes, elements and/or components.

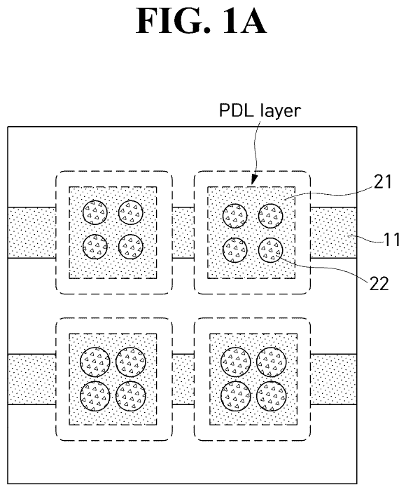

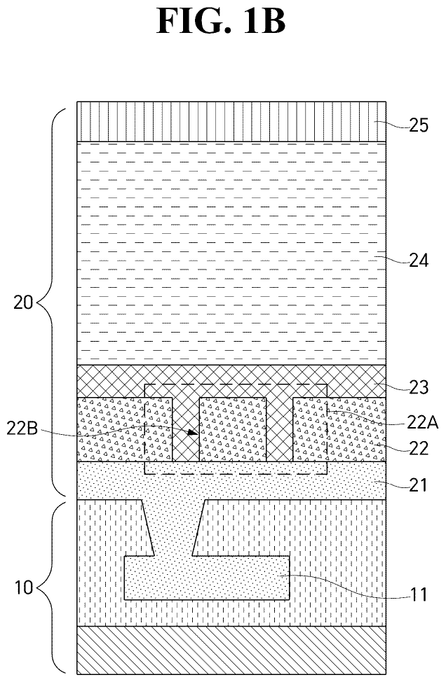

FIG. 1A is a schematic layout illustrating a subpixel of a monolithic meta organic light-emitting diode (OLED) according to an embodiment of the present disclosure, and FIG. 1B is a schematic cross-sectional view illustrating a subpixel of the monolithic meta-OLED illustrated in FIG. 1A.

Referring to FIGS. 1A and 1B, the subpixel of the monolithic meta-OLED according to an embodiment of the present disclosure may include a circuit substrate 10 and a meta-OLED 20 formed on the circuit substrate 10. Here, FIG. 1A is a diagram where some elements (for example, an OLED layer 24 and a top electrode 25) illustrated in FIG. 1B are transparently processed.

The circuit substrate 10 may be a substrate where a circuit for controlling and driving a subpixel of the meta-OLED 20 is integrated, and for example, may be a substrate of a silicon (Si) material to which complementary metal-oxide-semiconductor (CMOS) technology is applied. In this case, the circuit substrate 10 may be referred to as a Si CMOS backplane.

The meta-OLED 20 may include a meta surface layer 22 formed on the bottom electrode 21, a transparent conductive layer 23 formed on the meta surface layer 22, an OLED layer 24 formed on the transparent conductive layer 23, and a top electrode 25 formed on the OLED layer 24.

The bottom electrode 21 may be referred to as an anode or a pixel pad, which is electrically connected to a power line 11 formed in the circuit substrate 10. When the bottom electrode 21 is referred to as an anode, the top electrode 25 may be referred to as a cathode.

The bottom electrode 21 may function as an electrical contact which connects a circuit (for example, thin film transistor (TFT)), integrated into the circuit substrate 10, to the OLED layer 24 through the power line 11.

The meta surface layer 22 may be a layer which is formed on the bottom electrode 21 and replaces a conventional color filter. The meta surface layer 22 may function as a resonant structure which controls optical performance such as the reflection, refraction, and absorption of light. Such a structure may decrease optical loss and may induce efficient light emission, and thus, an ultra-high resolution and high color purity of an OLED may be implemented.

When seen from above, the meta surface layer 22 may include a meta surface structure 22A including a plurality of cylinders arranged in a matrix form. A material of the meta surface layer 22 may use, for example, a dielectric such as silicon dioxide (SiO₂) or a metal material such as gold (Au), silver (Ag), aluminum (Al), or copper (Cu). A space between the cylinders in the meta surface structure 22A may function as a connection path 22B which electrically connects the bottom electrode 21 to the OLED layer 24. The connection path 22B may be filled with the transparent conductive layer 23, and the bottom electrode 21 may be electrically connected to the OLED layer 24 by the transparent conductive layer 23.

A material of the transparent conductive layer 23 may use, for example, transparent conductive oxide (TCO), and an example of TCO may include indium tin oxide (ITO).

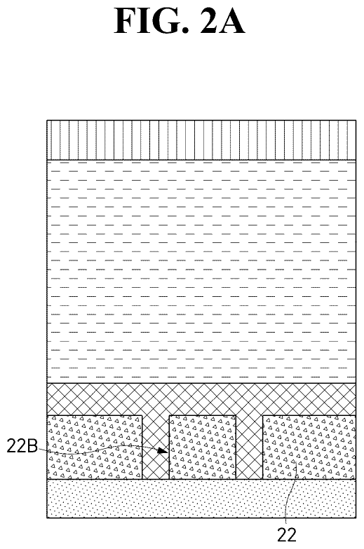

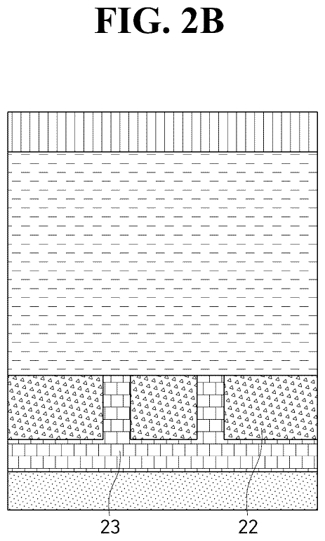

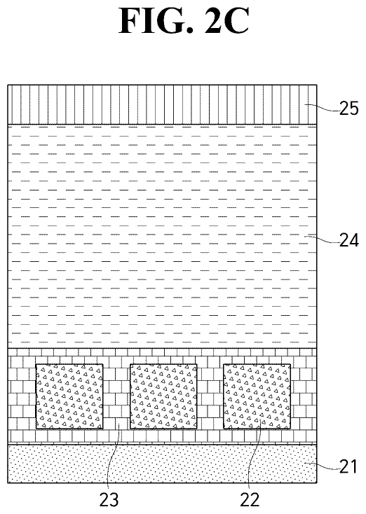

FIGS. 2A to 2C are cross-sectional views illustrating various structures of a meta surface layer according to an embodiment of the present disclosure.

A structure of the meta surface layer illustrated in FIG. 2A may be a structure where the meta surface layer 22 having a meta surface structure including cylinders arranged in a matrix form is formed on the bottom electrode 21, and then, a conductive polymer layer is formed in the connection path 22B which is a space between the cylinders. Here, a material of the conductive polymer layer may use polyaniline (PANI), polypyrrole (PPy), polythiophene (PTh), polyacetylene, polyphenylene vinylene (PPV), or poly(3,4-ethylenedioxythiophene (PEDOT).

A structure of the meta surface layer 22 illustrated in FIG. 2B may be a structure where the transparent conductive layer 23 is formed on the bottom electrode 21, and then, the meta surface layer 22 is formed on the transparent conductive layer 23.

A structure of the meta surface layer 22 illustrated in FIG. 2C may be a structure where the transparent conductive layer 23 is formed on the bottom electrode 21, and the meta surface layer 22 is formed on the transparent conductive layer 23, and then, the meta surface layer 22 is formed on the transparent conductive layer 23 once more.

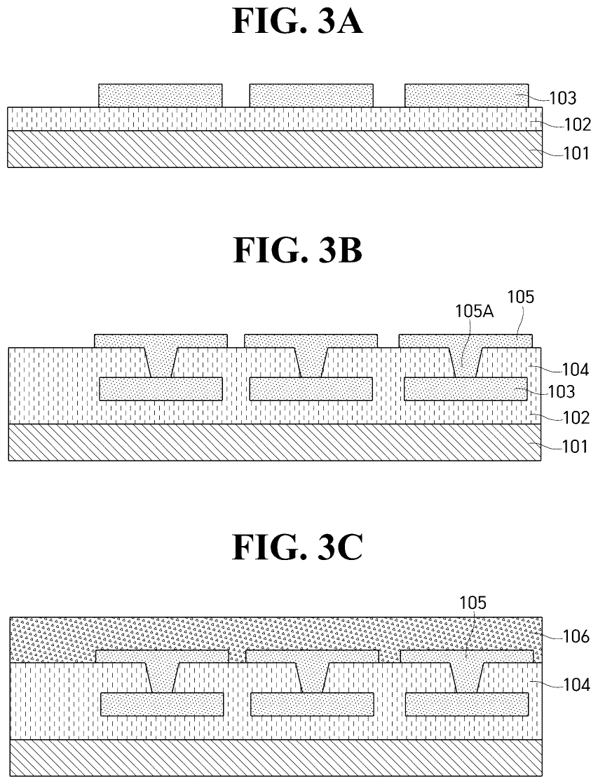

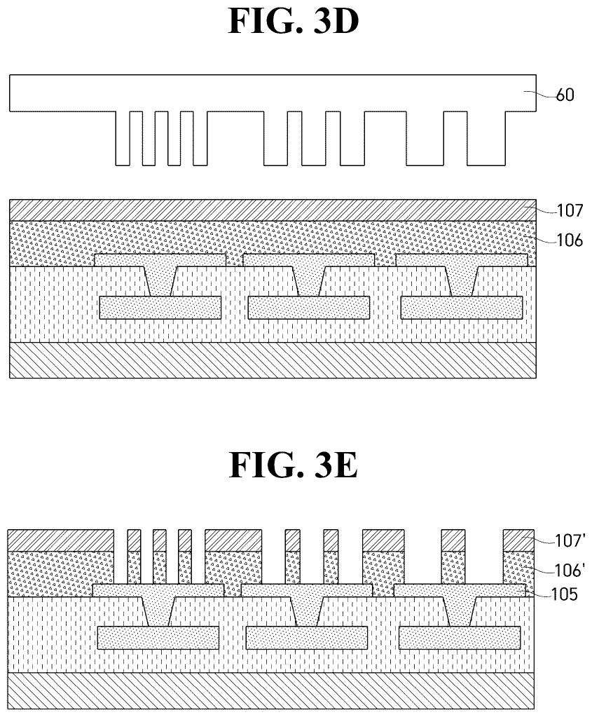

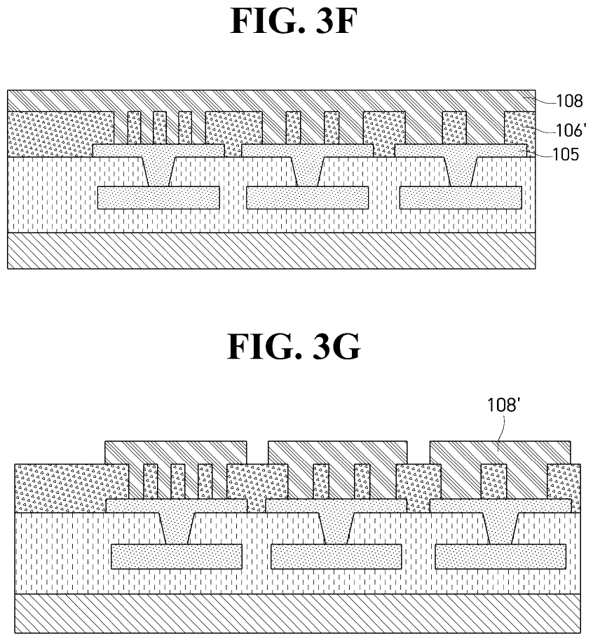

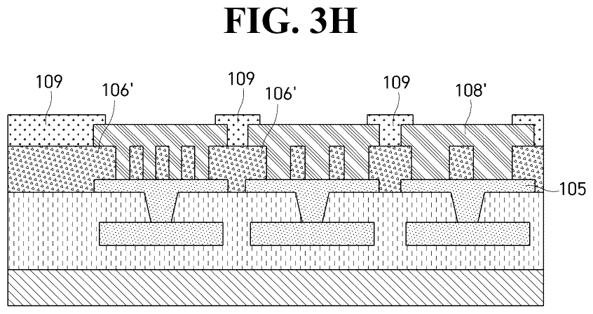

FIGS. 3A to 3H are cross-sectional views for describing a manufacturing process of a monolithic meta-OLED according to an embodiment of the present disclosure.

Referring to FIG. 3A, first, a base substrate 101 may be prepared. The base substrate 101 may be a substrate of a silicon material. Subsequently, a buffer oxide layer 102 may be formed on the base substrate 101 by using a deposition process such as a chemical vapor deposition (CVD) process and/or a thermal oxidation process. The buffer oxide layer 102 may alleviate a stress of the base substrate 101, or may function as an interlayer dielectric. Subsequently, a patterned power line 103 may be formed on the buffer oxide layer 102. For example, first, a metal layer (for example, aluminum, copper, or the like) for forming the power line 103 may be formed on the buffer oxide layer 102 by a sputtering process or an evaporation process, and then, the metal layer may be patterned by performing a photolithography process and an etching process, and thus, the patterned power line 103 may be formed on the buffer oxide layer 102.

Subsequently, referring to FIG. 3B, a planarization layer 104 covering the patterned power line 103 may be formed on the buffer oxide layer 102 by using a deposition process and a planarization process (for example, a chemical mechanical polishing (CMP) process). Subsequently, a via 105A may be formed by using a photolithography process and an etching process, and then, the bottom electrode 105 electrically connected thereto through the via 105A may be formed on the planarization layer 104.

Subsequently, referring to FIG. 3C, a meta surface material 106 covering the bottom electrode 105 may be formed on the planarization layer 104 by using a deposition process. The meta surface material 106 may use metal or a dielectric such as SiO₂. The deposition process for forming the meta surface material 106 may use a thermal oxidation process, a CVD process, an atomic layer deposition (ALD) process, a sputtering process, or an electron-beam evaporation process.

Subsequently, referring to FIG. 3D, a resist 107 may be formed on the meta surface material 106 by using a coating process. The resist 107 may use a polymer material such as an ultraviolet (UV) curing polymer or polymethyl methacrylate (PMMA). Subsequently, the resist 107 may be patterned by using a nanoimprint lithography (NIL) process. For example, when pressure is applied to the resist 107 by a nanoimprint stamp 60, a nanopattern of the nanoimprint stamp 60 may be transferred to the resist 107, and thus, the resist 107 may be patterned.

Subsequently, referring to FIG. 3E, a patterned resist 107′ may etch (pattern) the meta surface material 106 by using a mask. Accordingly, a meta surface layer 106′ having a meta surface structure including a plurality of cylinders may be formed.

Subsequently, referring to FIG. 3F, the patterned resist 107′ remaining on the meta surface layer 106′ may be removed by using an etching process such as a plasma etching process, a wet etching process, or an ashing process, and a transparent conductive layer 108 such as ITO may be formed on a surface of the meta surface layer 106′ which is exposed by removing the patterned resist 107′ and the bottom electrode 105 which is upward exposed in a process of etching the meta surface material 106. In this case, a conductive polymer material instead of ITO may be used as the transparent conductive layer 108. A deposition process for forming the transparent conductive layer 108 may use a sputtering process or a CVD process. Subsequently, a surface of the transparent conductive layer 108 may be planarized by using a chemical mechanical polishing (CMP) process, and then, organic contaminants, dusts, or fine particles remaining on the surface of the planarized transparent conductive layer 108 may be removed through a surface treatment process such as a cleaning process, a UV-ozone treatment process, or a plasma treatment process.

Subsequently, referring to FIG. 3G, a patterned transparent conductive layer 108′ may be formed by patterning the transparent conductive layer 108, so as to define a pixel area. A photolithography process and an etching process may be performed by patterning the transparent conductive layer 108. The etching process may include a wet etching process or/and a dry etching process.

Subsequently, referring to FIG. 3H, a patterned pixel define layer (PDL) 109 representing a boundary of the pixel area may be formed on the meta surface layer 106′ which is upward exposed in a process of patterning the transparent conductive layer 108. To form the PDL 109, first, a PDL material may be uniformly coated on the patterned transparent conductive layer 108′ and the upward exposed meta surface layer 106′. Here, the PDL material may use polyimide, acryl, or the other organic dielectric. A process of coating the PDL material may use a spin coating process, a slot die coating process, or an inkjet printing process. Subsequently, the PDL material may be removed by using a photolithography process and an etching process so that a surface of the transparent conductive layer 108 corresponding to the pixel area is upward exposed. Accordingly, a patterned PDL 109 may be formed.

Subsequently, although not shown, the OLED layer 24 illustrated in FIG. 1B may be formed on the upward exposed transparent conductive layer 108 by using a spin coating process, an evaporation process, and a thermal evaporation process. Here, the OLED layer 24 may be formed in a structure where a hole transport layer (HTL), an organic emission layer (EML), and an electron transport layer (ETL) are sequentially stacked. Subsequently, the top electrode 25 illustrated in FIG. 1B may be formed on the OLED layer 24 by using a thermal evaporation process and/or an E-beam evaporation process. The present disclosure may be characterized in that the patterned meta surface layer 106′is formed to have a meta surface structure on the bottom electrode 105 which is a pixel pad and may not be characterized in a structure of each of the OLED layer 24 and the top electrode 25, and thus, a process drawing on the elements 24 and 25 may be omitted in the present disclosure.

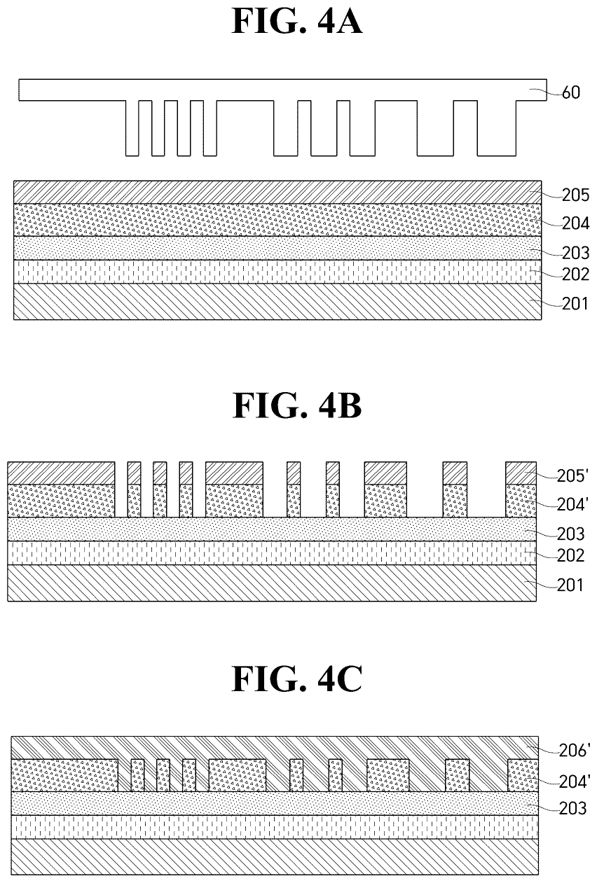

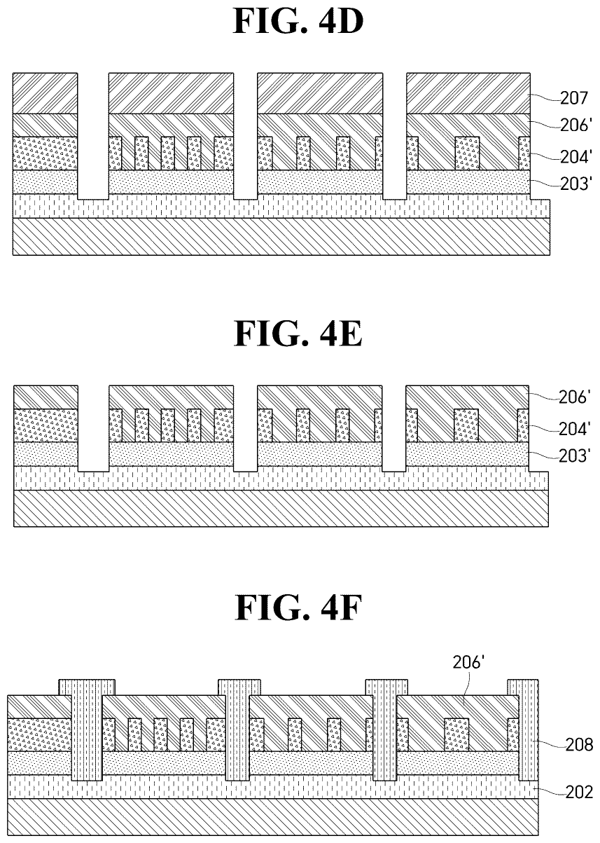

FIGS. 4A to 4F are cross-sectional views for describing a manufacturing process of a monolithic meta-OLED according to another embodiment of the present disclosure.

First, referring to FIGS. 4A and 4B, a buffer oxide layer 202, a metal layer 203 for pixel pad (bottom electrode), a meta surface material 204, and a resist 205 may be sequentially deposited on a base substrate 201. Subsequently, the nanoimprint lithography process of patterning the resist 205 may be performed by using the nanoimprint stamp 60. Subsequently, the meta surface material 204 may be patterned (etched) by using a patterned resistor 205′ as a mask through the nanoimprint lithography process. Accordingly, a meta surface layer 204′ having a meta surface structure including a plurality of cylinders may be formed.

Subsequently, referring to FIG. 4C, the patterned resistor 205′ may be removed by using an etching process such as an oxygen plasma etching process, a wet etching process, a dry etching process, or an ashing process. Subsequently, a transparent conductive layer 206 covering the meta surface layer 204′ may be deposited on the metal layer 203 for pixel pad. Subsequently, a surface treatment process and a planarization process of planarizing a surface of the transparent conductive layer 206 may be further performed.

Subsequently, referring to FIG. 4D, in order to define a pixel area, the metal layer 203 for pixel pad, the meta surface layer 204′, and the transparent conductive layer 206 may be simultaneously or sequentially etched (patterned) by using a pixel pattern mask 207. At this time, a portion of the buffer oxide layer 202 upward exposed may be etched in a process of etching the metal layer 203 for pixel pad, the meta surface layer 204′, and the transparent conductive layer 206.

The etching process may use a dry etching process or a wet etching process, and in order to simultaneously etch a multilayer including different materials, it may be needed to precisely control a process parameter. Based on such as etching process, a bottom electrode 203′ corresponding to the pixel area may be formed from the metal layer 203 for pixel pad (bottom electrode), the meta surface layer 204′ corresponding to the pixel area may be formed, and a transparent conductive layer 206′ corresponding to the pixel area may be formed.

Subsequently, referring to FIG. 4E, a pixel pattern mask 207 remaining on the etched transparent conductive layer 206′ may be removed through a wet chemical stripping process or a dry stripping process.

Subsequently, referring to FIG. 4F, a PDL 208 filing a space formed in a process of patterning the metal layer 203 for pixel pad, the meta surface layer 204′, and the transparent conductive layer 206 in FIG. 4D may be formed. For example, a PDL material may be deposited on the transparent conductive layer 206′ corresponding to the space and the pixel area, and then, the PDL 208 defining a pixel boundary may be formed by patterning the PDL material by using a photolithography process and an etching process. Subsequently, the OLED layer (24 of FIG. 1) and the top electrode (25 of FIG. 1) may be formed on the patterned transparent conductive layer 206′ upward exposed. A process of forming the elements 24 and 25 may be replaced with the above descriptions.

According to embodiments of the present disclosure, a color filter of a conventional monolithic OLED may be replaced with a meta surface, and thus, an ultra-high resolution and high color purity may be implemented.

It will be apparent to those skilled in the art that various modifications and variations may be made in the present invention without departing from the spirit or scope of the inventions. Thus, it is intended that the present invention covers the modifications and variations of this invention provided they come within the scope of the appended claims and their equivalents.

What is claimed is:

1. A method of manufacturing a monolithic meta organic light-emitting diode (OLED), the method comprising:
a step of forming a power line on a base substrate;
a step of forming a planarization layer covering the power line on the base substrate;
a step of forming a bottom electrode electrically connected to the power line on the planarization layer;
a step of forming a meta surface layer on the bottom electrode;
a step of forming a transparent conductive layer on the meta surface layer;
a step of forming an OLED layer on the transparent conductive layer; and
a step of forming a top electrode on the OLED layer.

2. The method of claim 1, wherein the step of forming the meta surface layer on the bottom electrode comprises a step of forming the meta surface layer on the bottom electrode by using a nanoimprint lithography process.

3. The method of claim 1, wherein the step of forming the meta surface layer on the bottom electrode comprises:
a step of depositing a meta surface material covering the bottom electrode on the planarization layer;
a step of coating a resist on the meta surface material;
a step of patterning the resist by using a nanoimprint stamp; and
a step of etching the meta surface material by using a patterned resist as a mask to form the meta surface layer.

4. The method of claim 3, wherein the meta surface material is a dielectric or metal.

5. The method of claim 1, wherein, when seen from above, the meta surface layer comprises a plurality of cylinders arranged in a matrix form.

6. The method of claim 1, further comprising:
between the step of forming the transparent conductive layer on the meta surface layer and the step of forming the OLED layer on the transparent conductive layer,
a step of patterning the transparent conductive layer; and
a step of forming a pixel define layer representing a boundary of a pixel area on the meta surface layer upward exposed in a process of patterning the transparent conductive layer.

7. A method of manufacturing a monolithic meta organic light-emitting diode (OLED), the method comprising:
a step of sequentially forming a buffer oxide layer, a metal layer for pixel pad, and a meta surface material on a base substrate;
a step of patterning the meta surface material to form a meta surface layer;
a step of forming a transparent conductive layer covering the meta surface layer on the metal layer for pixel pad;
a step of simultaneously or sequentially patterning the metal layer for pixel pad, the meta surface layer, and the transparent conductive layer by using a pixel mask pattern;
a step of removing the pixel mask pattern, and then, forming a pixel define layer filling a space formed in a process of patterning the metal layer for pixel pad, the meta surface layer, and the transparent conductive layer;
a step of forming an OLED layer on a patterned transparent conductive layer upward exposed; and
a step of forming a top electrode on the OLED layer.

8. The method of claim 7, wherein the step of patterning the meta surface material to form the meta surface layer comprises a step of patterning the meta surface material by using a nanoimprint lithography process to form the meta surface layer.

9. The method of claim 7, wherein the step of patterning the meta surface material to form the meta surface layer comprises:
a step of coating a resist on the meta surface material;
a step of patterning the resist by using a nanoimprint stamp; and
a step of patterning the meta surface material by using a patterned resist as a mask.

10. The method of claim 7, wherein the meta surface material is a dielectric or metal.

11. The method of claim 7, wherein the step of patterning the meta surface material to form the meta surface layer comprises a step of forming the meta surface layer including a plurality of cylinders arranged in a matrix form by using a nanoimprint lithography process.

12. A monolithic meta organic light-emitting diode (OLED) comprising:
a circuit substrate;
a bottom electrode disposed on the circuit substrate;
a meta surface layer having a meta surface structure including a plurality of cylinders disposed on the bottom electrode;
a transparent conductive layer disposed between an upper portion of the meta surface layer and the plurality of cylinders;
an OLED layer disposed on the transparent conductive layer; and
a top electrode disposed on the OLED layer.

13. The monolithic meta-OLED of claim 12, wherein the meta surface layer comprises a dielectric or metal.

14. The monolithic meta-OLED of claim 12, wherein the transparent conductive layer is an indium tin oxide (ITO) layer or a conductive polymer layer.
